(19) United States
(12) Patent Application Publication
(10) Pub. No.: US 2016/0285360 A1
(43) Pub. Date: Sep. 29, 2016

(54) METHOD AND APPARATUS FOR ELECTROMAGNETIC INTERFERENCE REDUCTION

(71) Applicant: Ford Global Technologies, LLC, Dearborn, MI (US)

(72) Inventors: Mohamed ELSHAER, Canton, MI (US); Chingchi CHEN, Ann Arbor, MI (US)

(21) Appl. No.: 14/667,131

(22) Filed: Mar. 24, 2015

(51) Int. Cl. H02M 1/44; H03H 7/01; H02M 3/04

(52) U.S. Cl. CPC H02M 1/44; H02M 3/04; H03H 7/0115

(57) ABSTRACT

A DC to DC power converter includes switching circuitry and an LC filter. The LC filter includes a capacitor electrically connected between an inductor and coil. The inductor and coil are wound in a same direction. The coil is positioned and oriented relative to the inductor so that current from the switching circuitry flowing through the inductor and coil results in inductive coupling between the inductor and coil. This coupling increases a frequency at which a parasitic inductance and capacitance of the capacitor resonate.

### TECHNICAL FIELD

The present disclosure generally relates to electrical noise filtering, and more particularly, to filtering of high-frequency noise from electrical circuits.

### BACKGROUND

Vehicle power converters, such as DC to DC power converters, may generate noise during operation. Passive filters, such as LC filters, can be used to reduce this noise but may present cost, weight and packaging issues.

### SUMMARY

A converter includes switching circuitry and an LC filter having a capacitor electrically connected between an inductor and a coil. The coil is wound in a same direction as the inductor. The coil is oriented relative to the inductor such that current from the switching circuitry flowing through the inductor and coil results in inductive coupling between the inductor and coil. This inductive coupling increases a frequency at which a parasitic inductance and capacitance of the capacitor resonate.

An LC filter includes an inductor, a coil wound in a same direction as the inductor, and a capacitor electrically connecting the inductor and coil. The coil is positioned relative to the inductor so that current flow through the inductor and coil results in inductive coupling between the inductor and coil, which increases a resonate frequency of a parasitic inductance and capacitance of the capacitor.

A method for reducing noise associated with a switching circuit includes directing current from the switching circuit through an inductor and coil, having a same winding direction, of an LC circuit including a capacitor electrically connecting the inductor and coil to inductively couple the inductor and coil to increase the frequency at which a parasitic inductance and capacitance of the capacitor resonate.

### BRIEF DESCRIPTION OF THE DRAWINGS

FIG. 1 is a schematic diagram for measuring self-parasitic contributions to filter attenuation of components of an LC filter;

FIGS. 2A-2C are graphs illustrating self-parasitic, input and output impedances, and input-to-output attenuation of the components in FIG. 1;

FIG. 3 is an LC filter circuit topology having a coil between an inductor and an output bus bar;

FIG. 4 is a graph depicting the LC filter having the coil between the inductor and the output bus bar for decreasing the required inductance caused by parasitic cancellation at the output bus bar;

FIG. 5 is a two port linear circuit representing the LC filter with the coil;

FIG. 6 is a T-equivalent circuit model of the filter shown in FIG. 5;

FIG. 7 is an example of the LC filter designed for a specific attenuation and switching frequency; and

FIG. 8 is a graph illustrating a comparison in performance between the LC filter arranged with and without the coil configuration.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The embodiments of the present disclosure generally provide for a plurality of circuits or other electrical devices. All references to the circuits and other electrical devices and the functionality provided by each, are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microprocessors, integrated circuits, memory devices (e.g., FLASH, random access memory (RAM), read only memory (ROM), electrically programmable read only memory (EPROM), electrically erasable programmable read only memory (EEPROM), or other suitable variants thereof) and software which co-act with one another to perform operation(s) disclosed herein. In addition, any one or more of the electric devices may be configured to execute a computer-program that is embodied in a non-transitory computer readable medium that is programmed to perform any number of the functions as disclosed.

The disclosure provides a cost effective solution to improve filtering of noise at a bus bar. In a vehicle electric system, a common mode noise and differential mode noise may be created based on one or more power supplies. The vehicle electric system may use input and/or output filters to attenuate the noise from the one or more power supplies. The input and output filters may have degraded performance based on component self-parasitic coupling between filter components and other components in the circuit in close proximity with the filter. A filter design may require additional components to avoid the degraded performance caused by the noise generated from switching circuitry. The additional components and/or an increase in size of components may cause an increase in cost of the filter. For example, at high frequencies the components of the filter may affect inductances based on the negative effects of a capacitor branch resulting in degradation of the filter.

The proposed design is to use a low-pass filter (LC filter) with an extended wire coupling design (a coil) between an inductor of the filter and an output of the bus bar to allow for the cancellation of the effective inductance of the capacitor branch of the LC low-pass filter. The proposed design of the LC filter configured with the coil may also maintain low bus bar inductance. The concept includes a geometrical construction of the output bus bar wiring forming a coil that may comprise a loop or a loop with multiple turns between the output bus bar and the inductor of the filter.

The disclosed coil design from the output bus bar to the filter inductor improves the high frequency performance of the LC low-pass filter. The design includes the use of the coil having an extended wire forming a loop or a loop with multiple turns and coupled between the components of the LC filter. The coil design provides a mutual inductance as an additional series inductance with the filter inductor and also as an additional series inductance with the output bus bar.

A vehicle electrical/electronic component and/or subsystem may be designed based on one or more Electromagnetic Compatibility (EMC) requirements. The EMC requirements ensure that the component and/or subsystem do not exceed or are within a predefined threshold for noise. A component exceeding a predefined threshold for noise may affect the performance of other components and/or subsystems.

For example, a DC to DC power converter may be regulated based on the EMC requirements shown below:

TABLE 1

| | | Frequency | Limits | |
|---|---|---|---|---|
| Band # | RF Service | Range (MHz) | Average (dbuV) | Quasi-Peak |
| EU1 | Long Wave | 0.15-0.28 | 77 | 89 |
| G1 | Medium Wave | 0.53-1.7 | 54 | 66 |
| JA1 | FM 1 | 76-90 | — | 36 |
| G3 | FM 2 | 87.5-108 | — | 36 |

As shown in Table 1, the medium wave (AM) radio frequency (RF) operates in a range of 0.53 to 1.7 MHz (megahertz) at a 54 dbuV (decibels relative to one microvolt). Therefore, the converter providing noise within a frequency range of 0.53 MHz and 54 dbuV may cause interference to the AM frequency. The converter may be coupled to the filter to reduce and/or substantially eliminate the noise. The filter is used to remove unwanted frequency components from the signal, to enhance wanted ones, or both.

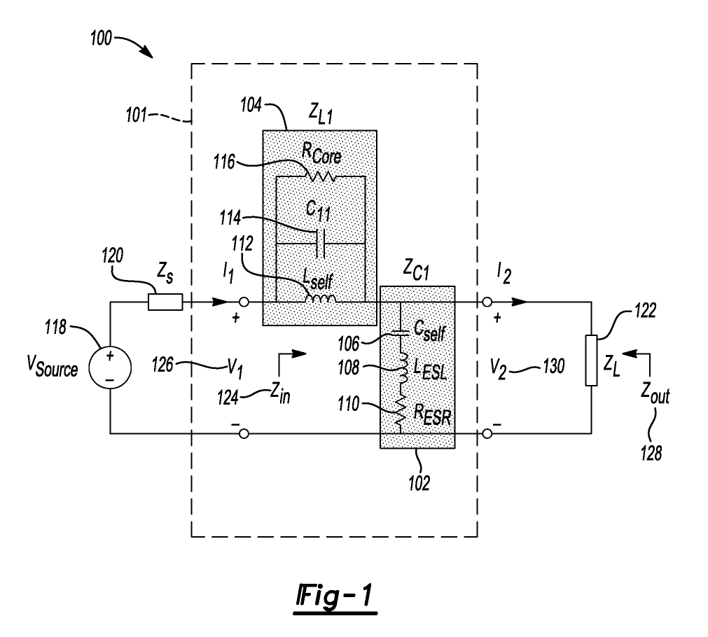

The filter (e.g., LC low pass filter) may ensure that the electrical/electronic component does not interfere with the RF services of other components and/or subsystems. Before coupling a low-pass filter with the electrical/electronic component, analysis may be performed to determine what size of filter is need to remove unwanted frequency. For example, the low-pass filter with an extended wire coupling design (i.e., the coil) may be constructed based on an LC filter model used to determine filter attenuation based on the contribution of components as shown in FIG. 1.

FIG. 1 is an electrical schematic 100 for measuring contributions of components self-parasitic to filter attenuation of one or more components of the LC filter. The electrical schematic 100 comprises the LC filter 101 having a capacitor equivalent circuit 102 and an inductor equivalent circuit 104. The inductor equivalent circuit 104 and the capacitor equivalent circuit 102 are configured to form the LC filter 101. The LC filter 101, as a low-pass filter, is configured to attenuate signals with frequencies higher than a cutoff frequency. The capacitor equivalent circuit 102 includes a capacitor C_{self} 106, an inductor L_{ESL} 108, and a resistor R_{ESR} 110 in series with each other. The inductor L_{ESL} 108 represents the LC filter's 101 capacitor's 102 parasitic inductance. The inductor equivalent circuit 104 (e.g., an attenuation circuit) includes an inductor L_{self} 112, a capacitor Cₜₜ 114, and a resistor R_{Core} 116 configured in parallel with each other. The inductor L_{self} 112 is the inductor equivalent circuit 104 self-inductance. The capacitor Cₜₜ 114 is the LC filter inductor's intertwining capacitance. The inductor equivalent circuit 104 and the capacitor equivalent circuit 102 are configured to measure the filter attenuation of the LC filter 101.

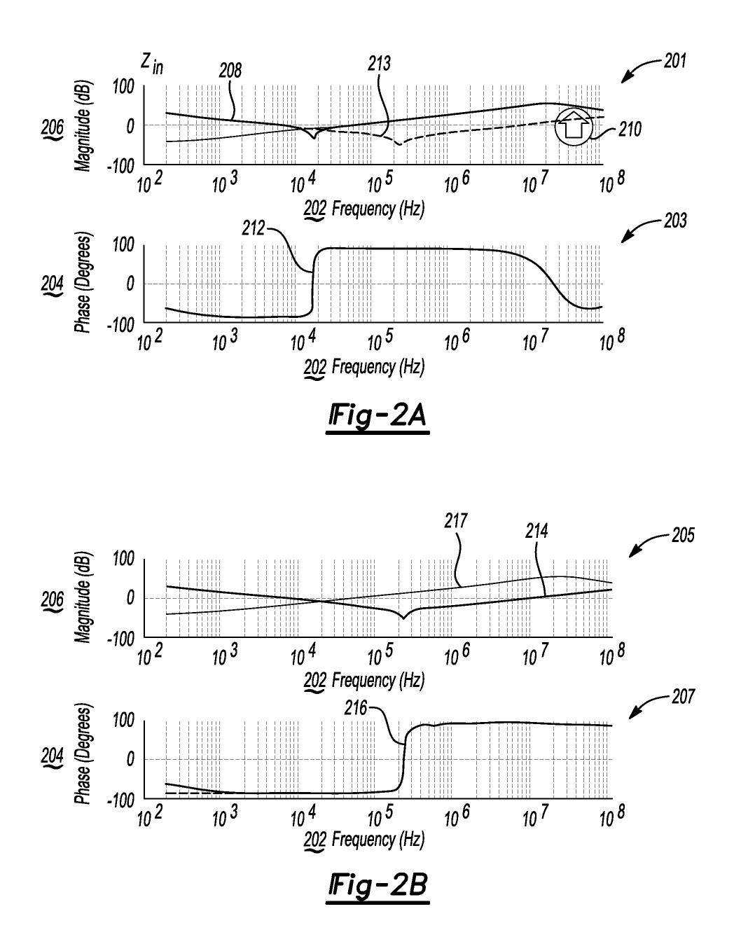

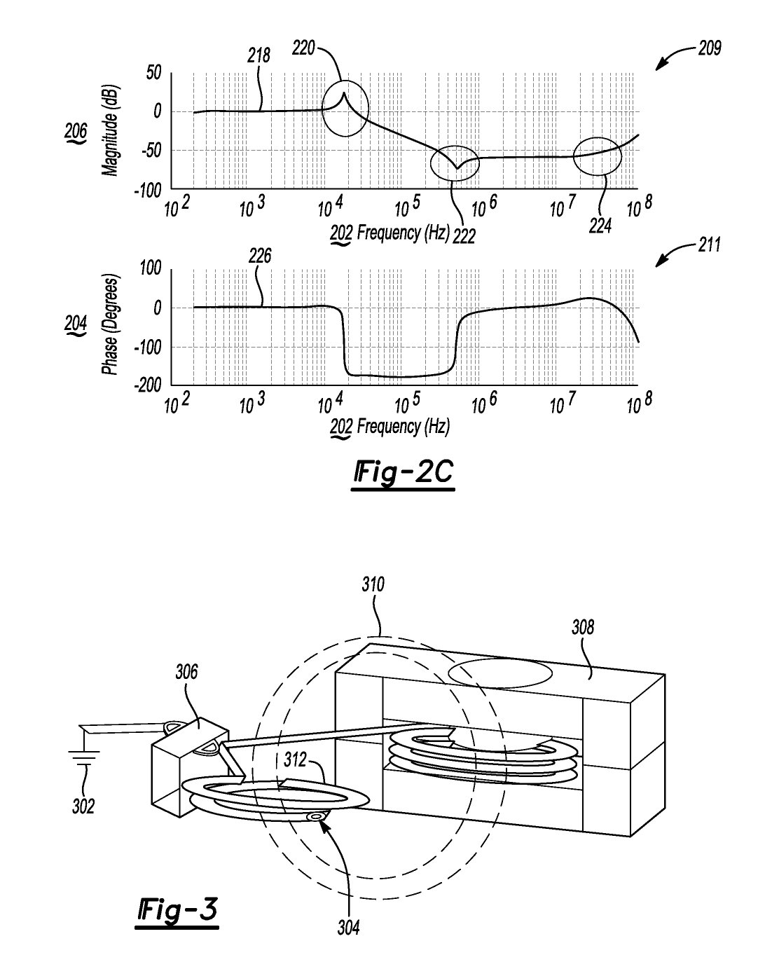

The electrical schematic 100 is a circuit 100 that includes a voltage source 118 to simulate the noise being injected to the LC filter 101. The circuit 100 further includes source impedance 120 that models the noise source impedance. The LC filter 101 may be configured to filter frequencies generated by this noise source. The design of the LC filter 101 may increase the size of the inductor 112 and capacitor 106 based on the magnitude of noise being generated and the desired level of attenuation. The LC filter 101 is loaded by a load impedance 122. The load impedance 122 provides output impedance Zₒᵤₜ 128 of the circuit 100 across a second voltage V₂ 130. The performance of the LC filter 101 may be characterized by calculating the voltage ratio of the second voltage V2 130 to a first voltage V1 126. The performance of the LC filter 101 is illustrated on the graphs in FIG. 2A-2C.

The inductor equivalent circuit 104 may provide degradation data to analyze the performance of the LC filter 101 such that the degradation to filter attenuation is depicted due to its self-parasitics between the inductor L_{self} 112 and capacitor Cₜₜ 114. For example, the performance of the filter 101 may be improved by maximizing input impedance Zᵢₙ 124 of the inductor L_{ESL} 108 and resistor C_{self} 106 based on a first resonant frequency f₁ as shown in equation (1) below. As shown in FIG. 1, the input impedance Zᵢₙ 124 of the circuit 100 is across the first voltage V₁ 126.

The circuit 100 provides the variables to calculate contributions of component self-parasitic that may cause filter attenuation. Based on the circuit 100, the resonant frequency for the LC filter 101 may be calculated based on the following equations:

$$\begin{matrix}{f}_{1} = \frac{1}{2 π \sqrt{{L}_{ESL} {C}_{self}}} & ( 1 ) \\ {f}_{2} = \frac{1}{2 π \sqrt{{C}_{Self} {L}_{ESL}}} & ( 2 ) \\ {f}_{3} = \frac{1}{2 π \sqrt{{L}_{Self} {C}_{tt}}} & ( 3 )\end{matrix}$$

FIG. 2A includes two graphs 201, 203 illustrating input impedance Zᵢₙ 124 of the electrical schematic 100 across the first voltage V₁ 126. The graphs 201, 203 have an x-axis representing frequency 202 and a y-axis representing magnitude 206 and phase 204, respectively. A magnitude graph 201 illustrates the input impedance Zᵢₙ 124 magnitude 208 across a frequency range. As illustrated in the magnitude graph 201, the input impedance Zᵢₙ 124 performance begins to degrade based on capacitor Cₜₜ 114. As shown in the graph 201, the capacitor Cₜₜ 114 magnitude 213 models the inductor's 104 intertwining capacitance. This capacitance appears in parallel with the inductor's inductance causing a resonance to occur at a third resonant frequency f₃ having a value approximately 10⁷ Hz as calculated in equation (3) above. For frequencies greater than the third resonant frequency f₃, the input impedance Zᵢₙ 124 is dominated by the Cₜₜ 114 impedance. Hence, high frequency performance is degraded as illustrated by the input impedance Zᵢₙ 124 magnitude 208.

The input impedance magnitude 208 begins to decrease 210 at a high frequency. The phase graph 203 illustrates an input impedance phase 212 across a frequency range. As shown in the graph 203, at the third frequency f₃ (approximately 10⁷ Hz) the phase is changed from positive ninety degrees to negative ninety degrees indicating that the input impedance is capacitive and dominated by the Cₜₜ 114 impedance.

FIG. 2B includes two graphs 205, 207 illustrating output impedance Zₒᵤₜ 128 of the electrical schematic 100 across the second voltage V₂ 130. The graphs 205, 207 have an x-axis representing frequency 202 and a y-axis representing magnitude 206 and phase 204, respectively. A magnitude graph 205 illustrates an output impedance Zₒᵤₜ magnitude 214 across a frequency range. As illustrated in the magnitude graph 205, the output impedance 128 performance begins to degrade based on Cₜₜ 114 magnitude 217 that models the inductor's self-impedance. The LC filter attenuation may be improved by minimizing the output impedance based on reducing the inductance in the capacitor branch.

The output impedance Zₒᵤₜ magnitude 214 begins to increase at high frequency after the capacitor 106 resonates with the inductor 108 at a second resonant frequency f₂ which is a value greater than 10⁵ Hz as calculated by equation (2) above. The phase graph 207 illustrates an output impedance Zₒᵤₜ phase 216 across a frequency range. As shown in the graph 207, the phase shift (from negative ninety degrees to positive ninety degrees) of the LC filter 101 occurs at relatively a low frequency. The phase shift illustrates when the capacitor branch inductance is resonating with the capacitor's 102 self-capacitance. For example, the output impedance Zₒᵤₜ phase 216 illustrates that the capacitor C_{self} 106 in the LC filter 101 is no longer performing after the second resonate frequency f₂, resulting in degradation in the filter attenuation.

The high frequency attenuation of the LC filter 101 may be improved by eliminating the resonance between the capacitor's parasitic inductance and its parasitic capacitance which occurs at the second frequency f₂. Hence, the LC filter's output impedance 128 is maximized at high frequency.

FIG. 2C includes two graphs 209, 211 illustrating a measured filter attenuation of the LC filter 101. The graphs 209, 211 illustrate the performance of the LC filter 101 at different frequencies. The graphs 209, 211 have an x-axis representing frequency 202 and a y-axis representing magnitude 206 and phase 204, respectively. The measured filter attenuation is captured by the configuration of the LC filter as shown in FIG. 1.

A magnitude graph 209 illustrates a filter attenuation magnitude 218 across a frequency range. As illustrated in the magnitude graph 209, the first (f₁) 220, second (f₂) 222, and third (f₃) resonant frequencies 224 provide noise affecting the filter attenuation magnitude 218 as calculated based on equations (1) through (3) above. The filter attenuation magnitude 218 indicates that the attenuation is at higher frequencies. The capacitor branch (inductor L_{ESL} 108 and resistor C_{self} 106) inductance resonates with the capacitor's self-capacitance as illustrated in the second (f₂) resonant frequency 222. The result of the second (f₂) resonant frequency 222 is degradation in the filter attenuation in the long wave interfering with the AM and FM bands as shown in Table 1. The effective parallel capacitance of the inductor resonates with the inductor's self-inductance at the third (f₃) resonant frequency 224. The third (f₃) resonant frequency 224 results in degradation in the filter attenuation in the FM band as shown in Table 1.

The phase graph 211 illustrates a filter attenuation phase 226 across a frequency range. As shown in the graph 211, the filter attenuation phase 226 indicates that the capacitor's effective inductance is a critical component for the filter performance.

In response to the filter performance being degraded at high frequencies and the fact the capacitor's effective inductance is a critical component for the filter performance requires an improved electric circuit topology to mitigate the excessive noise. The filter design may include an additional capacitance and/or inductance to the capacitor branch of the LC filter based on the excessive noise. The addition of a larger capacitor and/or inductor may increase the cost of the LC filter. In lieu of the additional capacitance and inductance, a circuit topology coupling between the output filter inductor and the output bus bar may substantially reduce the noise.

FIG. 3 is an LC filter circuit topology having a coil 312 between an inductor 308 and an output bus bar 304. The LC filter circuit topology 300 includes an output capacitor 306 and the inductor 308. The inductor 308 may be illustrated and modeled as the inductor equivalent circuit 104 as shown in FIG. 1. The capacitor 306 may be illustrated and modeled as the capacitor equivalent circuit 102 as shown in FIG. 1.

The capacitor 306 has one end connected to a ground 302 with the other end connected to the coil 312 between the inductor 308 and the output bus bar 304. The coil 312 (e.g., coupling connection) is configured to eliminate the resonance between the inductor's parasitic capacitance and the inductor's self-inductance (e.g., generate an effective inductance 310). The output bus bar 304 may have the coil 312 shaped to form a loop or a loop with multiple turns to generate the effective inductance 310. The coil may be configured with a number of turns based on a size of the inductor, capacitor, and/or a combination thereof. The coil may have a diameter based on the size of the inductor, capacitor, and/or a combination thereof.

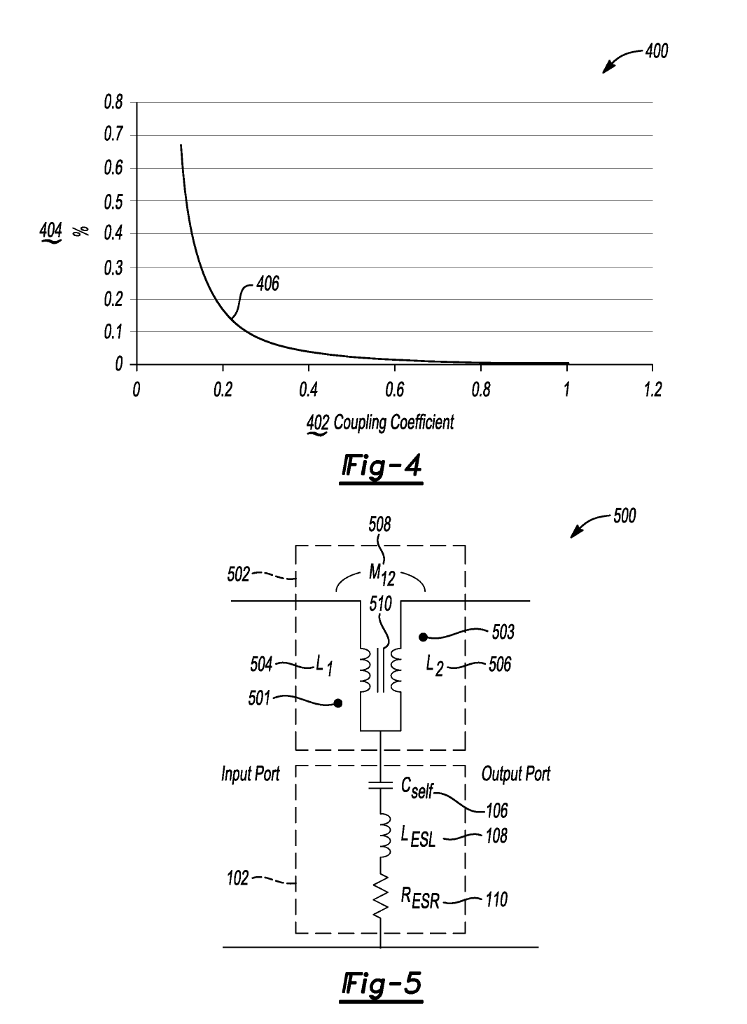

For example, the DC to DC power converter may have an LC filter configured with the coil 312 to eliminate noise generated at the converter's switching circuitry. The LC filter has the capacitor 306 electrically connected between the inductor 308 and the coil 312. The coil 312 is wound in a same direction as the inductor 308. The coil 312 is positioned and oriented between the inductor 308 and the output bus bar 304 so that current from the switching circuitry flows through the inductor and coil resulting in inductive coupling 310. The position and orientation (e.g., distance) of the coil to the inductor may be based on the size of the coil. The inductive coupling 310 between the coil 312 and inductor 308 increases a frequency that may cancel the effective inductance 310 in the capacitor branch as shown in FIG. 4.

FIG. 4 is a graph 400 depicting the LC filter 300 having the coil 312 decrease an inductance at the output bus bar 304. The graph 400 has an x-axis representing a coupling coefficient 402 and a y-axis representing a percentage of inductance at the bus bar 404. The bus bar inductance 406 decays as the coil 312 increases the number of loops between the output bus bar 304 and the inductor 308 of the LC filter.

As shown in FIG. 4, the bus bar inductance 406 exponentially decays as a function of increasing the coil between the output bus bar 304 and the filter inductor 308. For example, the output bus bar 304 may be connected to the coil 312 shaped to form a loop or a loop with multiple turns. The number of turns in the coil 312 (e.g., coupling connection loop) may cancel the effective inductance of the capacitor branch while maintain low bus bar inductance.

FIG. 5 is a two port linear circuit representing the LC filter with the coil, according to one embodiment. The circuit 500 includes the capacitor equivalent circuit 102 and a coupled inductor equivalent circuit 502 having an inductor coupled to a bus bar. The coupled inductor 502 includes an input inductor L₁ 504, and an output inductor L₂ 506 that are coupled 510 together. The input inductor L₁ 504 and output inductor L₂ 506 have windings in the same direction. The input inductor L₁ 504 has a counter clockwise (CC) winding 501. The output inductor L₂ 506 is wound in a CC winding 503. The coupled inductor 502 generates a coupling M₁₂ 508 between the input inductor L₁ 504, and output inductor L₂ 506.

For example, the input inductor L₁ 504 may be the inductor 308 of the LC Filter and the output inductor L₂ 506 may be the coil 312 connected to the output 304 of the bus bar as shown in FIG. 3. The inductor 308 and coil 312 may have windings in the same direction so that current flow through the inductor and coil result in inductive coupling.

As illustrated in FIG. 5, the coupling 510 between the two inductors 504, 506 may be through the air. In another embodiment, the coupling 510 between the two inductors 504, 506 may share the same core; therefore the inductors 504, 506 are wound around the same core. The coupled inductor 502 may be configured to cancel the effective inductance of the capacitor branch without the addition of a larger capacitor and/or inductor for the LC circuit.

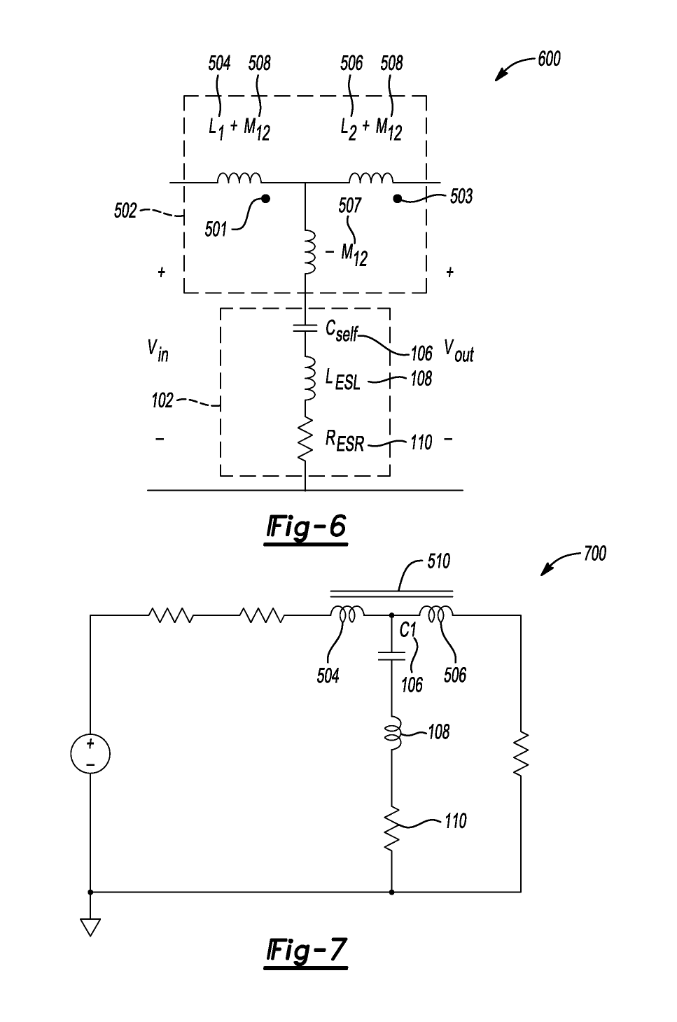

FIG. 6 is a design circuit 600 having the capacitor branch inductance circuit 102 used to calculate the mutual inductance generated by the coupling M₁₂ 508 of the coupled inductor 502 in FIG. 5. The design circuit 600 may be used to quantify the mutual inductance generated by the coupling of the coupled inductor 502 and illustrates the components in the capacitor branch. The capacitor branch circuit 102 may be represented as the equivalent circuit for the capacitor 102 as shown in FIG. 1. The capacitor equivalent circuit 102 includes the capacitor C_{self} 106, inductor L_{ESL} 108, and resistor R_{ESL} 110 in series.

In this embodiment, the coupled inductor 502 is illustrated as the input inductor L₁ 504 added by the generated coupling value M₁₂ 508 and the output inductor L₂ 506 added by the generated coupling value M₁₂ 508. The input inductor L₁ 504 and output inductor L₂ 506 have windings in the same direction and are in series. The generated coupling value M₁₂ 508 is illustrated as a negative generated coupling value 507 in series to the input inductor L₁ 504, and output inductor L₂ 506.

The design circuit 600 may use several equations to develop a low pass filter to meet an attenuation Gₐₜₜₑₙᵤₐₜₑ required by the electrical/electric component, subsystem, and/or system. For example, the following equations may be used to design a low pass filter required to achieve a minus thirty decibel (−30 dB) attenuation at the switching circuit having a frequency of one hundred kilohertz (kHz). The coupled inductor is configured and designed to cancel capacitor C_{self} 106 based on the following equation:

fₒ=f_{S}\sqrt{10^{G}^{ₐₜₜₑₙᵤₐₜₑ}^{/20}} (4)

wherein fₒ is frequency required by the low pass filter, f_{S} is the switching frequency, and Gₐₜₜₑₙᵤₐₜₑ is the attenuation. So based on our example above, if the switching frequency f_{S} is equal to one hundred kilohertz (Khz) and the attenuation Gₐₜₜₑₙᵤₐₜₑ is minus thirty decibels, the frequency required fₒ will equal approximately 17782.8 Hz.

In response to the required frequency fₒ an appropriate value for the input inductor L₁ 504 and capacitor C_{self} 106 may be calculated based on the following equation:

fₒ=1/(2π\sqrt{L₁C_{self}}) (5)

To continue from our example above, based on the required frequency fₒ being approximately equal to 17782.8 Hz, the input inductor L₁ 504 may be approximately equal to 2.69 uH and capacitor C_{self} 106 may equal approximately 30 uF. The mutual inductance M₁₂ may need to match the capacitor branch inductance L_{ESL} as indicated based on the following equation below:

M₁₂=L_{ESL} (6)

Based on the example above, the measured capacitor branch inductance L_{ESL} (e.g., parasitic inductance) may be approximately equal to 14.8 nH. The coupled inductor 502 may determine the output inductor L₂ 506 required for a coupling coefficient k based on the following equation:

$$k = \frac{{M}_{12}}{\sqrt{{L}_{1} {L}_{2}}} \qquad ( 7 )$$

wherein the coupling coefficient k is the ratio of two inductance values. The coupling coefficient k is a selective value that may be chosen based on the design. To continue from our example above, if the selected coupling coefficient k is 0.1, the output inductor L₂ 506 may equal approximately 8.14 nH. In response to our example, the LC filter design may have the following assigned component values as illustrated in FIG. 7.

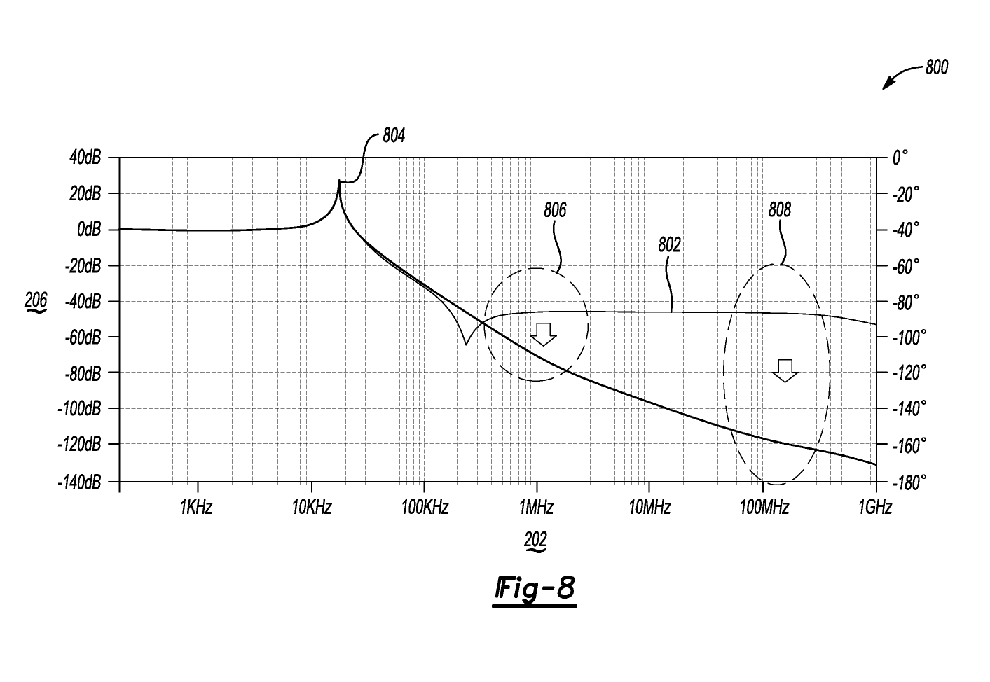

FIG. 7 is an exemplary example of an LC filter design for a specific attenuation and switching frequency. The LC filter design includes component values calculated from the example above using equations (4) though (7). The LC filter design having the coupled inductor may provide attenuation to eliminate the noise of an electric/electronic component and/or subsystem as shown in FIG. 8.

For example, the input inductor 504 may have a value of approximately 2.69 uH, the capacitor C_{self} 106 may have a value of approximately 30 uF, the capacitor branch inductance L_{ESL} 108 may have a value of approximately 14.8 nH, the resistor R_{ESL} 110 may have a value of approximately 1.68 mΩ, and the output inductor L₂ 506 may have a value of approximately 8.14 nH.

FIG. 8 is a graph illustrating a comparison in performance between the LC filter arranged with and without the coil configuration. The graph 800 includes an x-axis representing frequency 202 and a y-axis representing magnitude 206. The LC filter, not including a coupled inductor (i.e., the coil), may have an output impedance 802 degrading in performance at a higher frequency. For example, the LC filter may have an output impedance 802 interfering with the AM frequency band 806 and the FM frequency band 808 as labeled in Table 1.

The LC filter including a coupled inductor (i.e., the LC filter having the coil) may have an output impedance 804 lowering the magnitude at high frequencies. For example, the LC filter with the coupled inductor may substantially eliminate the interference with the AM frequency band 806 and the FM frequency band 808.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and can be desirable for particular applications.

1. A power converter comprising:
switching circuitry; and
an LC filter including a capacitor electrically connected between an inductor and a coil wound in a same direction as the inductor, wherein the coil is oriented relative to the inductor such that current from the switching circuitry flowing through the inductor and coil results in inductive coupling between the inductor and coil and a parasitic inductance and capacitance of the capacitor resonate at a target frequency.

2. The converter of claim 1, wherein the LC filter further includes a bus bar connecting the capacitor and inductor and wherein the coil is formed on an end of the bus bar.

3. The converter of claim 1, wherein the LC filter further includes a core and wherein the inductor and coil are each wound around the core.

4. The converter of claim 1, wherein a number of turns of the coil is based on a size of the inductor.

5. The converter of claim 1, wherein a diameter of the coil is based on a size of the inductor.

6. The converter of claim 1, wherein a size of the coil is based on a distance between the inductor and coil.

7. An LC filter comprising:
an inductor;
a coil wound in a same direction as the inductor; and
a capacitor electrically connecting the inductor and coil, wherein the coil is positioned relative to the inductor so that current flow through the inductor and coil results in inductive coupling between the inductor and coil and a parasitic inductance and capacitance of the capacitor resonate at a target frequency.

8. The filter of claim 7 further comprising a bus bar connecting the inductor and capacitor, wherein the coil is formed on an end of the bus bar.

9. The filter of claim 7 further comprising a core and wherein the inductor and coil are each wound around the core.

10. The filter of claim 7, wherein a number of turns of the coil is based on a size of the inductor.

11. The filter of claim 7, wherein a diameter of the coil is based on a size of the inductor.

12. The filter of claim 7, wherein a size of the coil is based on a distance between the inductor and coil.

13. A method for reducing noise associated with a switching circuit comprising:
directing current from the switching circuit through an inductor and coil, having a same winding direction, of an LC circuit including a capacitor electrically connecting the inductor and coil to inductively couple the inductor and coil and to cause a parasitic inductance and capacitance of the capacitor to resonate at a target frequency.

14. The method of claim 13, wherein the inductor and coil are each wound around a same core.
